(19) United States
(12) Patent Application Publication
(10) Pub. No.: US 2008/0210409 A1
(43) Pub. Date: Sep. 4, 2008

(54) Liquid Cooling System Fan Assembly

(76) Inventor: Anders Saksager, Aalborg (DK)

Correspondence Address: POLSTER, LIEDER, WOODRUFF & LUCCHESI, 12412 POWERSCOURT DRIVE SUITE 200, ST. LOUIS, MO, 63131-3615, US

(21) Appl. No.: 12/040,591

(22) Filed: Feb. 29, 2008

Related U.S. Application Data
(60) Provisional application No. 60/892,568, filed on Mar. 2, 2007.

(51) Int. Cl. F04D 29/38; F28D 15/00; H05K 7/20

(52) U.S. Cl. 165/104.33; 416/189

(57) ABSTRACT

A fan assembly configured for use with a radiator assembly in a cooling system. The fan assembly comprises a plurality of fan blades mounted about a central hub, and an annular ring member circumferentially coupled to the radially outboard end of each fan blade, coaxial with the central hub. The annular ring has an axial dimension equal to or exceeding the axial depth of each fan blade, whereby a radially outward flow of air from a high pressure region on one side of the fan blades is blocked from exiting the fan assembly radially during operation, and from flowing to a low pressure region on the opposite side of the fan blades. Axial air flow, driven by the rotational movement and configuration of the fan blades, is unimpeded by the annular ring member.

### CROSS-REFERENCE TO RELATED APPLICATIONS

The present application is related to, and claims priority from U.S. Provisional Patent Application Ser. No. 60/892,568 filed on Mar. 2, 2007, and which is herein incorporated by reference.

### STATEMENT REGARDING FEDERALLY SPONSORED RESEARCH

Not Applicable.

### BACKGROUND OF THE INVENTION

The present invention is related generally to cooling systems adapted for use in cooling heat sources such as integrated circuit components, processors, and memory modules in a computer system, and in particular to a fan assembly configured for directing a flow of air through a radiator within which liquid coolant is circulated to facilitate heat exchange between the air and the flow of cooling liquid.

Personal computer systems which are design for desktop or under-desk use, and which are typically characterized by a main-board or motherboard housed in a chassis or case, often provide one or more expansion slots into which auxiliary components may be installed. These auxiliary components may include network adapter circuit boards, modems, specialized adapters, and graphics display adapters. These auxiliary components may receive power through the connection to the motherboard, or through additional connections directly to a system power supply contained within the chassis or case. Additional components, such as hard drives, disk drives, media readers, etc. may further be contained within the chassis or case, and coupled to the system power supply and motherboard as needed.

During operation, the motherboard and various auxiliary components consume power and generate heat. To ensure proper functionality of the computer system, it is necessary to regulate the operating temperatures inside the environment of the chassis or case. Individual integrated circuits, especially memory modules and processors, may generate significant amounts of heat during operation, resulting in localized heat sources or hot spots within the chassis environment. The term “processors”, as used herein, and as understood by one of ordinary skill in the art, describes a wide range of components, which may include dedicated graphics processing units, microprocessors, microcontrollers, digital signal processors, and general system processors such as those manufactured and sold by Intel and AMD. Failure to maintain adequate temperature control throughout the chassis environment, and at individual integrated circuits, can significantly degrade the system performance and may eventually lead to component failure.

Traditionally, a single cooling fan is often associated with the system power supply, to circulate air throughout the chassis environment, and to exchange the high temperature internal air with cooler external air. However, as personal computer systems include increasing numbers of individual components and integrated circuits, and applications become more demanding on additional processing components such as graphics display adapters, a system power supply cooling fan may be inadequate to maintain the necessary operating temperatures within the chassis environment.

Specialized liquid cooling systems are available for some components in a personal computer system. Specialized liquid cooling systems typically provide a liquid coolant circulation pathway, which routes a thermal transfer liquid between a heat exchanger such as a radiator, and one or more heat source, such as a CPU, GPU, a memory module, a microprocessor, or transformer. At each heat source, the flow of liquid coolant is passed over a heat transfer component, commonly referred to as a cold plate, which is in contact with the heat source on one side, and the flow of liquid coolant on another side. Typically, a cold plate is constructed from a metal, such as copper, which has a good ability to transfer heat from the heat source to the liquid coolant. The surface of the cold plate in contact with the heat source is generally planar, facilitating a large region of contact, while the surface of the cold plate in contact with the liquid coolant flow may have a number of protrusions, fins, or foils extending there from to provide an increased surface area for the exchange of heat.

Heat which is transferred to the liquid coolant from the cold plate is subsequently extracted from the liquid coolant as the liquid coolant flows through a radiator assembly. The radiator assembly may be of conventional design, and includes a fan assembly such as shown in FIG. 1, which directs a flow of air through the various passages and radiating surfaces of the radiator assembly. During operation, the fan assembly operates almost continuously, and may generate a level of noise which is undesirable to individuals operating the computer system. For example, when the fan assembly is driven at a high rotational speed, as is necessary to move a large volume of air through the radiator assembly, the velocity difference between the fan blades and the surrounding structures (walls, guards, and the like) is quite high, resulting in the generation of noise as air flows around the fan blades from regions of hi pressure to low pressure.

Accordingly, it would be advantageous to provide a fan assembly configured for use with a radiator assembly such as is found in a liquid cooling system, and which is constructed to block at least one pathway for the flow of air from a region of high pressure to a region of low pressure, thereby reducing the level of noise generated during operation of the fan assembly.

### BRIEF SUMMARY OF THE INVENTION

Briefly stated, the present disclosure provides a fan assembly configured for use with a radiator assembly such as is found in a liquid cooling system. The fan assembly comprises a plurality of fan blades mounted about a central hub, and an annular ring member circumferentially coupled to the radially outboard end of each fan blade, coaxial with the central hub. The annular ring has an axial dimension equal to or exceeding the axial depth of each fan blade, whereby a radially outward flow of air from a high pressure region on one side of the fan blades is blocked from exiting the fan assembly radially during operation, and from flowing to a low pressure region on the opposite side of the fan blades. Axial air flow, driven by the rotational movement and configuration of the fan blades, is unimpeded by the annular ring member.

In an embodiment of the present invention, the annular ring member is integrally formed with the plurality of fan blades and the central hub.

In an alternate aspect of the present invention, the annular ring member is bonded to the plurality of fan blades.

The foregoing features, and advantages set forth in the present disclosure as well as presently preferred embodiments will become more apparent from the reading of the following description in connection with the accompanying drawings.

### BRIEF DESCRIPTION OF THE SEVERAL VIEWS OF THE DRAWINGS

In the accompanying drawings which form part of the specification:

FIG. 1 is a perspective illustration of a prior art fan assembly;

FIG. 2 is a perspective illustration of a fan assembly of the present disclosure including an annular ring member; and

FIG. 3 is a perspective illustration of a fan assembly of the present disclosure operatively coupled to a heat exchanger assembly.

Corresponding reference numerals indicate corresponding parts throughout the several figures of the drawings. It is to be understood that the drawings are for illustrating the concepts set forth in the present disclosure and are not to scale.

### DESCRIPTION OF THE PREFERRED EMBODIMENT

The following detailed description illustrates the invention by way of example and not by way of limitation. The description enables one skilled in the art to make and use the present disclosure, and describes several embodiments, adaptations, variations, alternatives, and uses of the present disclosure, including what is presently believed to be the best mode of carrying out the present disclosure.

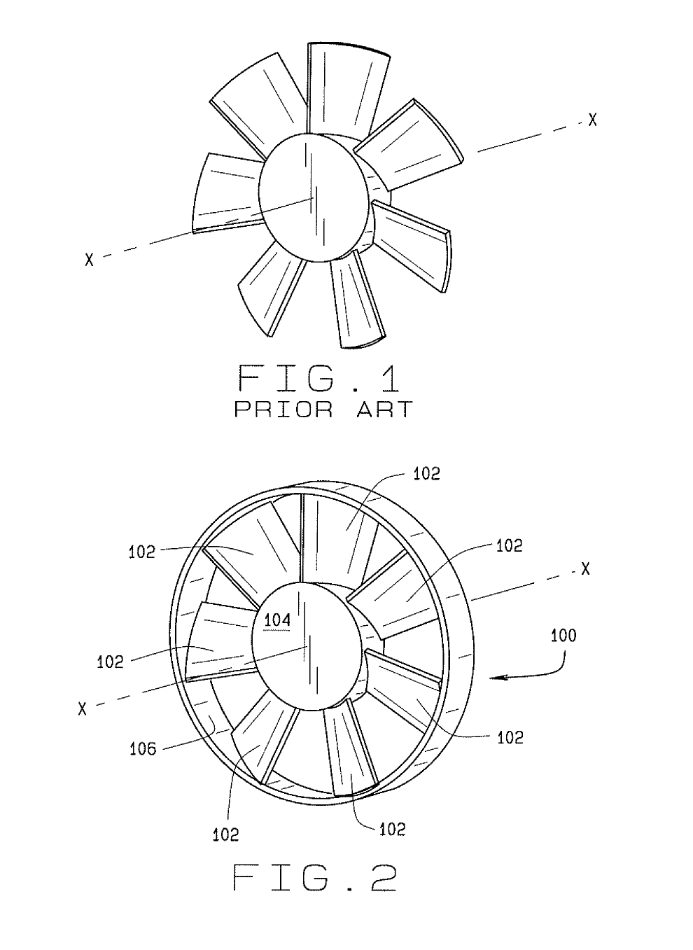

Turning to the FIG. 2, a fan assembly 100 of the present invention is shown configured for use with a radiator assembly such as is found in a liquid cooling system which circulates a flow of liquid coolant between a cold plate assembly drawing heat from a heat source and the radiator assembly for dispersing heat to the external environment. The fan assembly comprises a plurality of fan blades 102 mounted radially outward about a central hub 104, and an annular ring member 106 circumferentially coupled to the radially outboard end of each fan blade 102, coaxial about an axis “X” with the central hub 104. The annular ring member 106 has an axial width dimension equal to or exceeding the axial depth of each fan blade 102, whereby a radially outward flow of air from a high pressure region on one side of the fan blades is blocked from exiting the fan assembly in a radial direction during rotational operation. Additionally, air flow from the high pressure region on the leading side of each fan blade 102 during rotation of the fan assembly 100 is blocked from flowing around a radial edge of the fan blade 102 to a low pressure region on the trailing side of the fan blade 102. Axial air flow, driven by the rotational movement and configuration of the fan blades 102, is unimpeded by the annular ring member 106. Those of ordinary skill in the art will recognize that the leading and trailing edges of the fan blades 102, as well as the direction of axial air flow will be determined by the direction of rotation of the fan assembly 100.

During operation of the fan assembly 100, the annular ring member 106 rotates about the fan assembly axis X synchronously with the fan blades 102 and central hub 104, such that the relative rotation between the fan blades 102 and the annular ring member 106 is zero, thereby reducing the amount of noise generated by turbulent airflow between the fan blades 102 and the surrounding structures.

Preferably, the annular ring member 106 is a contiguous structure which is integrally formed with the fan blades 102 and central hub 104 of the fan assembly 100, such as by a molding operation. However, in alternate embodiments, the annular ring member 106 may be coupled to the radially outward ends of each fan blade 102 by means of a conventional bonding technique, such as with glue or welds.

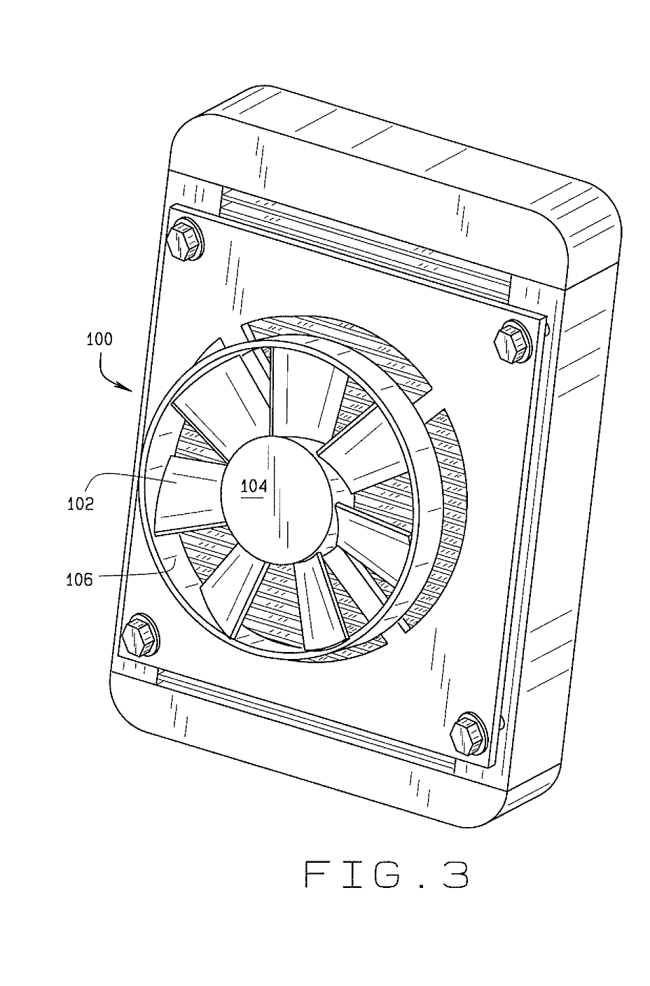

As shown in FIG. 3, the fan assembly 100 may be mounted in an operative relationship with a heat exchanger or radiator of an electronic component liquid cooling system, to draw or push a flow of air over the radiator components of the heat exchanger. As the air flows over the radiator components, thermal energy contained within a circulating liquid coolant is radiated from the heat exchanger and carried into the external environment by the airflow, thereby reducing the temperature of the liquid coolant. An airflow directing shroud or ducting may optionally be included in operative proximity to the fan assembly 100 or the heat exchanger, further facilitating the flow of air over the radiator components.

As various changes could be made in the above constructions without departing from the scope of the disclosure, it is intended that all matter contained in the above description or shown in the accompanying drawings shall be interpreted as illustrative and not in a limiting sense.

1. A fan assembly for use with a radiator assembly, comprising:
a central hub mounted for driven rotation about an axis;
a plurality of fan blades coupled at inboard radial ends to said central hub and extending radially outward there from, said plurality of fan blades contoured and aligned to axially drive a flow of air during rotation of said central hub and fan blades about the axis; and
a continuous annular ring member rigidly coupled to the outboard radial ends of each of said plurality of fan blades, said annular ring member configured to block a radially outward flow of air from said plurality of fan blades.

2. The fan assembly of claim 1 wherein said annular ring member has an axial dimension which is at least equal to an axial height of each of said plurality of fan blades.

3. The fan assembly of claim 1 wherein said annular ring member rotates about said axis synchronously with said plurality of fan blades, such that the relative speed difference between said annular ring member and said plurality of fan blades is zero.

4. The fan assembly of claim 1 wherein said central hub, said plurality of fan blades, and said annular member are integrally formed.

5. The fan assembly of claim 1 wherein said annular member is bonded to said outboard radial ends of each of said plurality of fan blades.

6. The fan assembly of claim 1 wherein said annular ring member blocks at least one airflow pathway over radial ends of said fan blades from a region of high pressure on a first side of said fan blades to a region of low pressure on a second side of said fan blades.

7. The fan assembly of claim 1 wherein the radiator assembly is associated with a liquid cooling system.

8. An improved liquid cooling system for electronic components, comprising:
at least one cold plate assembly for drawing heat from a heat source;
a heat exchanger assembly for releasing heat to an external environment;
a liquid coolant flow pathway circulating a liquid coolant between said at least one cold plate and said heat exchanger, said liquid coolant transporting thermal energy drawn from said heat source by said cold plate to said heat exchanger for release to said external environment; and
a fan assembly operatively coupled to said heat exchanger to drive a flow of ambient air through a plurality of radiator elements of said heat exchanger, said fan assembly including a central hub mounted for driven rotation about an axis, a plurality of fan blades coupled at inboard radial ends to said central hub and extending radially outward there from, said plurality of fan blades contoured and aligned to axially drive a flow of air during rotation of said central hub and fan blades about the axis; and a continuous annular ring member rigidly coupled to the outboard radial ends of each of said plurality of fan blades, said annular ring member configured to block a radially outward flow of air from said plurality of fan blades.

9. The improved liquid cooling system of claim 8 wherein said annular ring member rotates about said axis synchronously with said plurality of fan blades, such that the relative speed difference between said annular ring member and said plurality of fan blades is zero.

10. The improved liquid cooling system of claim 8 wherein said central hub, said plurality of fan blades, and said annular member are integrally formed.

11. The improved liquid cooling system of claim 8 wherein said annular ring member is configured to reduce airflow noise generated by a flow of air from a region of high pressure on one side of said fan blades to a region of low pressure on an opposite side of said fan blades.
